(19) United States
(12) Patent Application Publication
(10) Pub. No.: US 2024/0373541 A1
(43) Pub. Date: Nov. 7, 2024

(54) Construction Of A Target Assembly For A Compact D-D Or D-T Neutron Generator

(71) Applicant: Halliburton Energy Services, Inc., Houston, TX (US)

(72) Inventors: Zilu Zhou, Houston, TX (US); Weijun Guo, Houston, TX (US); Lesley Allison Fessler, Houston, TX (US)

(73) Assignee: Halliburton Energy Services, Inc., Houston, TX (US)

(21) Appl. No.: 18/310,974

(22) Filed: May 2, 2023

(51) Int. Cl. H05H 6/00; G01V 5/10

(52) U.S. Cl. CPC H05H 6/00; G01V 5/105

(57) ABSTRACT

A method for forming a neutron generating tube. The method may include brazing a welding ring to a neutron generating tube at a first open end, brazing a welding lip to a target rod, and disposing the target rod into the neutron generating tube, wherein the welding lip is at least in part in contact with the welding ring. The method may further include welding the welding lip to the welding ring to form a vacuum envelope, disposing a copper tubing at a second open end of the neutron generating tube opposite the first open end, and pinching off the copper tubing to form a sealed vacuum in the neutron generating tube.

### BACKGROUND

Wellbores drilled into subterranean formations may enable recovery of desirable fluids (e.g., hydrocarbons) using a number of different techniques. During drilling operations, slickline operations, or during wireline operations, measurements may be taken to determine the presence of oil, water, gas, and/or the like. One such device that may be utilized for these measurements may be a pulsed neutron tool. The pulsed neutron tool may comprise a pulsed neutron generator (PNG) that may operate and function to transmit neutrons into a formation for either logging while drilling (LWD) or wireline logging measurements.

Generally, a PNG may comprise a compact deuterium and tritium (D/T) neutron generator, which may be widely used in a downhole nuclear logging tool for oil and/or gas well measurements, in an environment of elevated temperatures. A D/T neutron generator may comprise a sealed tube as vacuum housing, a gas reservoir for storing D/T gas, an ion source for generating ions which are accelerated by a high voltage (HV) system, and a target which also contains the D/T gas for facilitating the D-T fusion reactions in the presence of bombardment of D/T ions to generate neutrons.

Presently, many neutron generating tubes utilize hot-cathode ion source technology, where a dispenser (hot cathode) is introduced to emit electrons for a direct ionization of gas molecules to produce the D/T atomic and molecular ions. Given a 50 mA (Iₑ) electron emission, a relatively low gas pressure of a few mTorr, a 100 μA (Iᵢₒₙ) ion beam may be routinely extracted either in a CW (continuous wave) or in a pulsed mode and accelerated to bombard a target (a metal film also containing D/T molecules) which is powered at HV of 100 kV. This gives a neutron yield of about 3×10⁸ n/sec with a lifetime of roughly 1000 hours.

However, there are multiple challenges in constructing a target assembly for neutron generating tube. For example, complex tube structure and compact geometry make the target assembly construction difficult. Due to sputtering of target film materials coming from the ion beam bombardment, the inner surface of insulating vacuum housing walls may be coated from deposition of sputtered metal particles, reducing the neutron generation tube lifetime. Further, due to development of avalanche from charged particles inside the tube acceleration column created by the HV, arcing may be prevalent, which may reduce operational stability. Additionally, target thermal heating may produce target degassing (of D/T molecules), which may reduce the neutron yield generated by the neutron generating tube.

### BRIEF DESCRIPTION OF THE DRAWINGS

These drawings illustrate certain aspects of some examples of the present disclosure and should not be used to limit or define the disclosure.

FIG. 1 illustrates a downhole tool in a wireline configuration, in accordance with examples of the present disclosure.

FIG. 2 is a diagram of illustrative embodiments of a pulsed-neutron logging tool.

FIG. 3A-3B are diagrams of alternative embodiments of a pulsed-neutron logging tool.

FIG. 4 illustrates the energy of a neutron as it interacts in the present disclosure.

FIG. 5 illustrates an example of a neutron generating tube.

FIG. 6 illustrates an example of the neutron generating tube with a hot cathode ion source.

FIG. 7 illustrates a workflow for constructing the neutron generating tube.

FIG. 8 illustrates construction of at least a part of the neutron generating tube.

FIG. 9 illustrates a conductive coating ring disposed in the neutron generating tube.

FIGS. 10A and 10B illustrate different examples of a target assembly.

FIGS. 11A and 11B illustrate placement of the target assemblies in the neutron generating tube.

FIG. 12 is a graph of metal properties of the target assembly as the target assembly is exposed to different temperatures.

FIG. 13 illustrates a mechanical assembly for the neutron generating tube.

### DETAILED DESCRIPTION

The present disclosure generally relates to systems and methods for forming at least a part of a neutron generating tube, which may be utilized as a neutron source in a pulsed neutron generator. As discussed below, neutron generating tube may be constructed utilizing an open structure with one or more metal washers used as electrodes and ceramic housing rings as insulating spacers in a brazed stack. This may allow for ease of construction and provide overall robustness to the neutron generating tube.

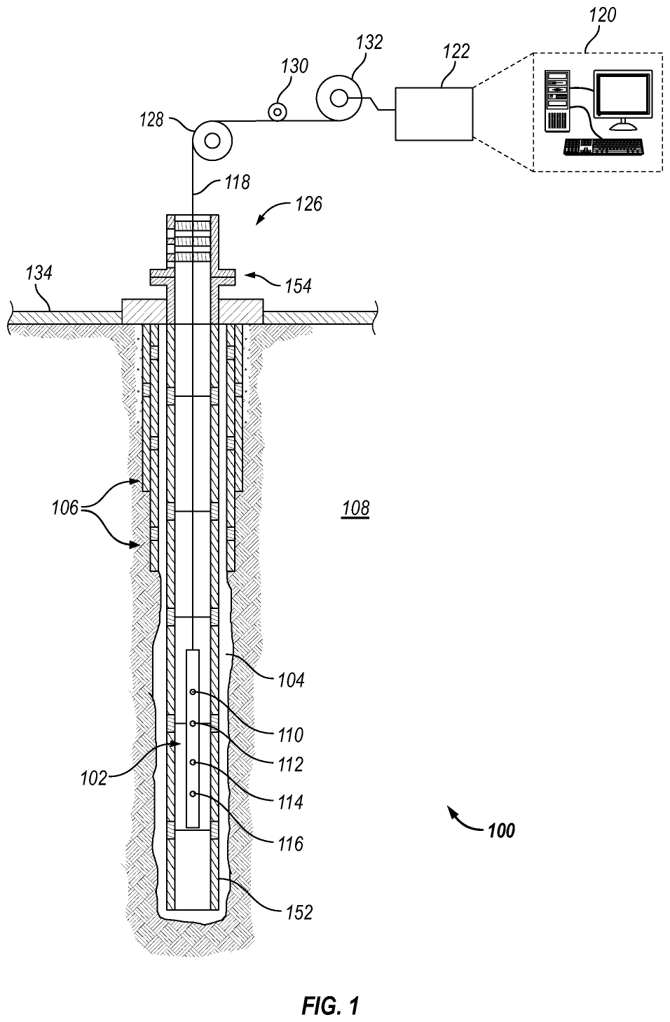

FIG. 1 illustrates logging/measuring operation 100, as disclosed herein, utilizing a pulsed-neutron logging tool 102. FIG. 1 illustrates a cross-section of borehole 104 with a pulsed-neutron logging tool 102 traveling through casing string 106. Borehole 104 may traverse through formation 108 as a vertical well and/or a horizontal well. Pulsed-neutron logging tool 102 contains a neutron generator 110, a first neutron detector 112, a second neutron detector 114, and a gamma ray detector 116. Pulsed-neutron logging tool 102 is suspended by a conveyance 118, which communicates power from a logging facility 120 to pulsed-neutron logging tool 102 and communicates telemetry from pulsed-neutron logging tool 102 to information handling system 122. In examples, pulsed-neutron logging tool 102 may be operatively coupled to a conveyance 118 (e.g., wireline, slickline, coiled tubing, pipe, downhole tractor, and/or the like) which may provide mechanical suspension, as well as electrical connectivity, for pulsed-neutron logging tool 102. Conveyance 118 and pulsed-neutron logging tool 102 may extend within casing string 106 to a depth within borehole 104. Conveyance 118, which may include one or more electrical conductors, may exit wellhead 126, may pass around pulley 128, may engage odometer 130, and may be reeled onto winch 132, which may be employed to raise and lower the tool assembly in borehole 104. Wellhead 126 allows for entry into borehole 104 and placement of pulsed-neutron logging tool 102 into pipe string 152. The position of pulsed-neutron logging tool 102 may be monitored in a number of ways, including an inertial tracker in pulsed-neutron logging tool 102 and a paid-out conveyance length monitor in logging facility 120.

Multiple such measurements may be desirable to enable the system to compensate for varying cable tension and cable stretch due to other factors. Information handling system 122 in logging facility 120 collects telemetry and position measurements and provides position-dependent logs of measurements from pulsed-neutron logging tool 102 and values that may be derived therefrom.

Pulsed-neutron logging tool 102 generally includes multiple instruments for measuring a variety of downhole parameters. Wheels, bow springs, fins, pads, or other centralizing mechanisms may be employed to keep pulsed-neutron logging tool 102 near the borehole axis during measurement operations. During measurement operations, generally, measurements may be performed as pulsed-neutron logging tool 102 is drawn up hole at a constant rate. The parameters and instruments may vary depending on the needs of the measurement operation.

Pulsed-neutron logging tool 102 operates by generating pulses of high energy neutrons that radiate from neutron generator 110 into the surrounding environment including borehole 104 and formation 108. The highly energetic neutrons entering the surrounding environment interact with atomic nuclei, inducing gamma ray radiation. Induced gamma rays and neutrons may be recorded by first neutron detector 112, second neutron detector 114, and/or gamma ray detector 116. The scattered neutrons and gamma ray spectrum may yield accurate knowledge of borehole and formation. Accurate knowledge of the borehole and formation identifies oil and gas in the formation as well as determining the flow in production wells.

Measurements taken by pulsed-neutron logging tool 102 may be gathered and/or processed by information handling system 122. For example, signals recorded by pulsed-neutron logging tool 102 may be sent to information handling system 122 where they may be stored on memory and then processed. The processing may be performed real-time during data acquisition or after recovery of pulsed-neutron logging tool 102. Processing may alternatively occur downhole on an information handling system disposed on pulsed-neutron logging tool 102 or may occur both downhole and at surface. In some examples, signals recorded by pulsed-neutron logging tool 102 may be conducted to information handling system 122 by way of conveyance 118. Information handling system 122 may process the signals, and the information contained therein may be displayed for an operator to observe and stored for future processing and reference. Information handling system 122 may also contain an apparatus for supplying control signals and power to pulsed-neutron logging tool 102.

In logging systems, such as, for example, logging systems utilizing the pulsed-neutron logging tool 102, a digital telemetry system may be employed, wherein an electrical circuit may be used to both supply power to pulsed-neutron logging tool 102 and to transfer data between information handling system 122 and pulsed-neutron logging tool 102. A DC voltage may be provided to pulsed-neutron logging tool 102 by a power supply located above ground level, and data may be coupled to the DC power conductor by a baseband current pulse system. Alternatively, pulsed-neutron logging tool 102 may be powered by batteries located within the downhole tool assembly, and/or the data provided by pulsed-neutron logging tool 102 may be stored within the downhole tool assembly, rather than transmitted to the surface during logging.

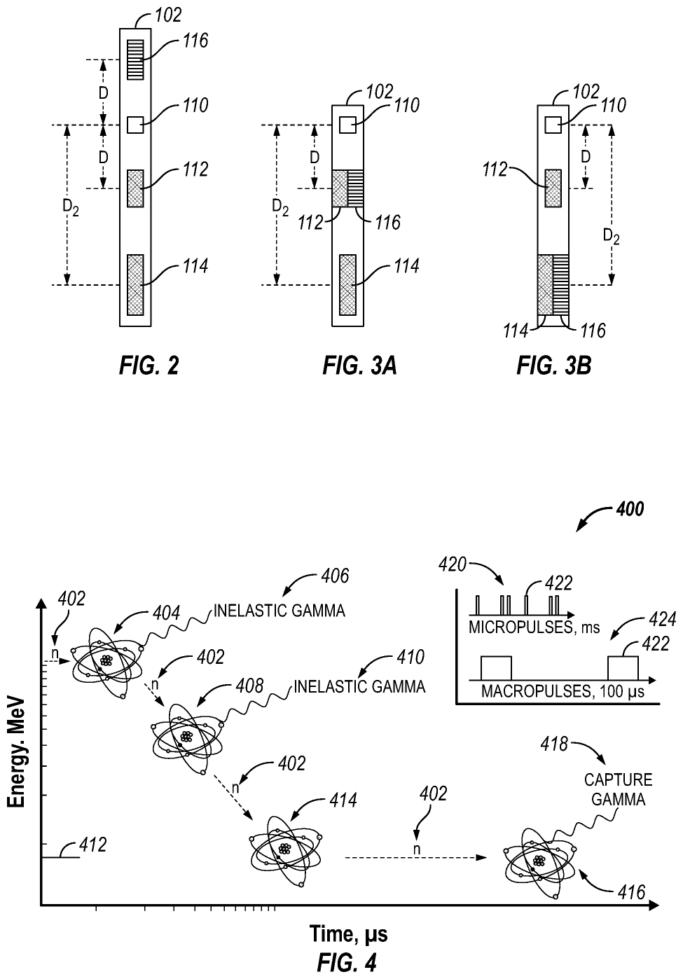

FIG. 2 shows a first illustrative setup of pulsed-neutron logging tool 102 having a pulsed neutron generator 110 that is positioned equidistant from a gamma ray detector 116 and a first neutron detector 112. In examples, pulsed neutron generator 110 may be replaced with a continuous neutron source such as Americium-Beryllium (Am—Be) chemical source. Pulsed-neutron logging tool 102 may also include a second neutron detector 114. The two neutron detectors 112 and 114 may be, respectively, termed the “near” and “far” neutron detectors. “Near” being the closest neutron detector to pulsed neutron generator 110 and “far” being the furthest neutron detector from pulsed neutron generator 110. Neutron detectors 112 and 114 may be designed to count thermal (around about 0.025 eV) and/or epithermal (between about 0.1 eV and 100 eV) neutrons. Suitable neutron detectors include Helium-3 (He-3) filled proportional counters, though other neutron counters may also be used. In examples, each neutron detector 112 and/or 114 may be implemented as a bank of individual detection devices. General, neutron porosity tool measurement techniques, the ratio of far-to-near neutron detector counts is indicative of formation porosity.

With continued reference to FIG. 2 gamma ray detector 116 may be implemented as a scintillation crystal coupled to a photomultiplier tube. As with neutron detectors 112 and/or 114, gamma ray detector 116 may be implemented as a bank of individual detection devices whose results are aggregated. In FIG. 2, gamma ray detector 116 is “co-distant” with the near neutron detector 112, i.e., it is positioned at the same distance D from neutron generator 110 as near neutron detector 112. As illustrated in FIG. 2, gamma ray detector 116 and first neutron detector 112 may be located in opposite directions from neutron generator 110.

FIGS. 3A and 3B illustrate alternative embodiments of pulsed-neutron logging tool 102. FIG. 3A shows an alternative example in which pulsed-neutron logging tool 102 has a gamma ray detector 116 and a near neutron detector 112 co-located, i.e., located side-by-side at the same distance D from the neutron generator 110. FIG. 3B shows yet another alternative example in which pulsed-neutron logging tool 102 has a gamma ray detector 116 and a far neutron detector 114 co-located at a distance D₂ from neutron generator 110.

Multiple neutron detectors 112, 114 of pulsed-neutron logging tool 102, enable pulsed-neutron logging tool 102 to measure formation porosity using any of the existing multiple-spacing techniques. In addition, the presence of gamma ray detector 116 having a common distance from neutron generator 110 with one of the neutron detectors 112 or 114, enables the measurement of elemental gamma ray spectroscopy, discussed below.

During measurement operations, neutrons emitted from neutron source or pulsed neutron generator 110 undergo neutron scattering and/or nuclear absorption when interacting with matter. Scattering may either be elastic (n, n) or inelastic (n, n′). In an elastic interaction a fraction of the neutrons kinetic energy is transferred to the nucleus. An inelastic interaction is similar, except the nucleus undergoes an internal rearrangement. Additionally, neutrons may also undergo an absorption interaction. During interactions, the elastic cross section is nearly constant, whereas the inelastic scattering cross section and absorption cross sections are proportional to the reciprocal of the neutron speed. For example, inelastic scatterings appear for fast neutrons in the MeV energy range, whereas absorptions happen when neutrons slowed down in the eV energy range.

FIG. 4 illustrates a graph 400 that depicts different scattering by a neutron 402. As illustrated, neutron 402 may be traveling at a fast speed with high kinetic energy and interacts with nuclei 404, releasing inelastic gamma 406 and lowering the energy state of neutron 402. After the interaction, neutron 402 contains too much energy to be absorbed, thus continuing its path until it interacts with nuclei 408 releasing inelastic gamma 410 and again lowering its energy state again. After the interaction, neutron 402 has kinetic energy close to target energy 412. Thus, when neutron 402 at target energy 412 interacts with nuclei 414 it will be captured. This interaction results in a rearranged nucleus 416 containing previously traveling neutron 402 and an emitted capture gamma 418. Sensing these events with pulsed-neutron logging tool 102 using first neutron detector 112, second neutron detector 114, and/or gamma ray detector 116 may allow for the identification of oil, gas, and/or water in borehole 104 and formation 108 (e.g., referring to FIG. 1).

With continued reference to FIG. 4, the neutron to gamma ray timing information may be utilized during measurement operations in which a pulsing neutron generator is utilized. In a sub-μs time domain, inelastic gamma rays dominate, whereas in a 10-1000 μs time range, gamma rays are captured. Insert 420 on FIG. 4 illustrates an example of neutron pulse 422 train and insert 424 shows the relationship of two adjacent neutron pulses 422 with a given pulse width and timing interval. Pulsing schemes allow isolation of inelastic and absorption gamma rays, and then allow elemental determinations of different nuclei in the bore hole, formation, or fluids.

Pulsed-neutron logging tool 102 is a complicated tool assembly that comprises sensitive and delicate parts that must survive the rigors of a downhole environment within borehole 104. A particularly sensitive part of pulsed-neutron logging tool 102 is neutron generator 110 (e.g., referring to FIG. 1). Discussed below are methods and systems that may be utilized to form a robust neutron generator 110 and a sequence to seal a neutron generating tube vacuum within neutron generator 110. Additionally, systems may further comprise a mechanism for damping arcing and to manage the target thermal heating during operation. These systems and methods may increase the neutron generating tube performance and lifetime capability of the neutron generating tube as compared to current technology.

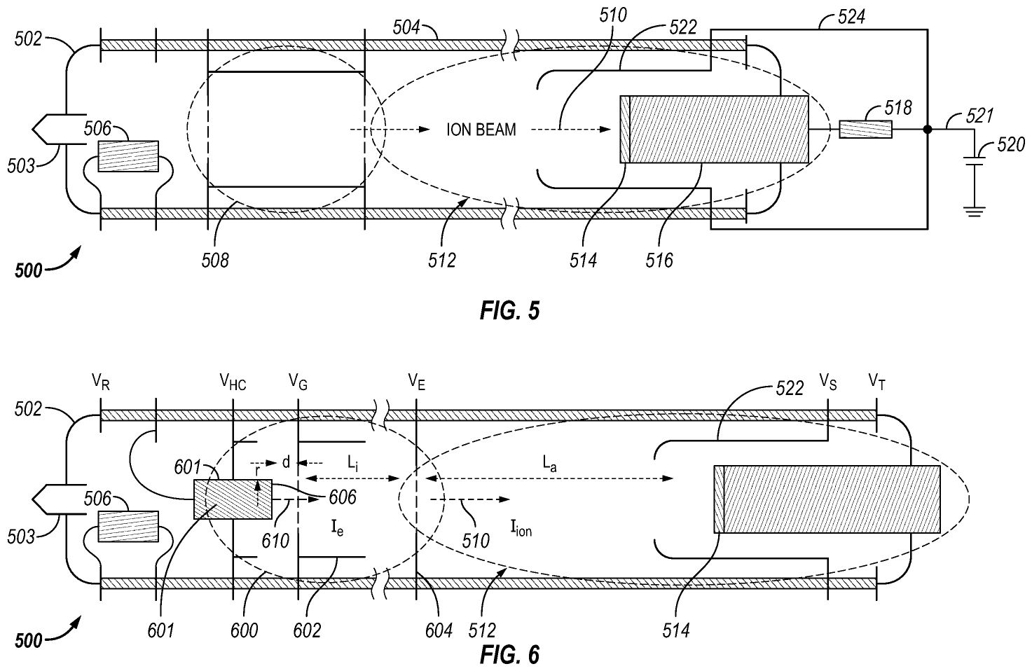

FIG. 5 illustrates a neutron generating tube 500 of neutron generator 110 (e.g., referring to FIG. 1). As illustrated, neutron generating tube 500 may comprise a vacuum housing 502, which may comprise a copper tubing 503 at the end part for vacuum processing. In examples, copper tubing 503 may be later pinched off to seal and create a sealed vacuum within neutron generating tube 500. Vacuum housing 502 may comprise insulating tube 504 for different voltage settings on different parts. In examples, insulating tube 504 may comprise glass and/or ceramic, which are materials that may provide both electrical insulation and enable the formation of a sealed vacuum during a sealing process. For example, insulating tube 504 may comprise one or more nickel-cobalt ferrous alloy washers used as electrodes and one or more ceramic housing rings as insulating spacers in a designed configuration with chosen geometry is brazed together. Within vacuum housing 502, a gas reservoir 506, which is typically porous Titanium or Zirconium metals for absorbing hydrogen gas, may be disposed for storing deuterium and tritium (D/T) gas. Generally, gas reservoir 506 may store a mixture of D₂ and T₂ gas, in a 50-50% ratio. The same D₂ and T₂ gas mixture may also be loaded in target film 514, which faces ion source 508. Target film 514 may be a coating disposed on a target rod 516, utilizing target rod 516 as a backing structure. Target rod 516, for example, may be Copper or other suitable metals which are good for electrical conductivity and thermal dissipation.

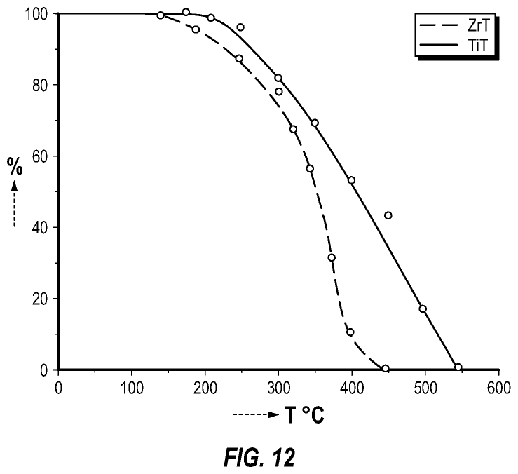

Target film 514 may comprise transitional metals, which may form metal hydrides to store hydrogen gas (e.g., D₂ and T₂ gas). Commonly used metals for target film 514 are Scandium, Titanium, Zirconium, or any combination of these materials in multi-layered form. These transitional metals have been widely studied for applications in neutron generating tubes 500 as both gas reservoir 506 and target film 514. As target film 514 for neutron generating tube 500, the hydrogen to metal atomic ratio inside a saturated metal may be as high as 2:1. Generally, a ratio of 1.8:1 seems to be a practical maximum, while a range of 1.6:1-1.7:1 is common. The ratio may depend at least in part on the ambient temperatures during operation. The ratio degrades at higher temperatures, and may even go down to 0:1, as Hydrogen degases from target film 514. FIG. 12 is a graph that shows residual Titanium percentage of target film 514 as a function of temperature after heating for one hour at each temperature setting. As seen in the graph, both Zirconium and Titanium start degassing at 200° C. or higher. Scandium may improve the performance of target film 514, which starts to degas at higher temperatures than both Zirconium and Titanium.

Referring back to FIG. 5, during operations, an ion beam 510 from ion source 508 with 100 μA current may be transmitted to bombard target film 514 normally at 100 kV. Thus, there is roughly ten Watts heating power to target film 514 and target rod 516. This may elevate the body temperature of target rod 516 above ambient, often with a ΔT=80-100° C., which may result in degassing of D/T gas from target film 514, such as, Titanium. A decreased D/T gas concentration inside a target film 514 of Titanium may result in a reduced neutron yield for target assembly 512.

As illustrated in FIG. 5, ion source 508 for generating an ion beam 510 may be disposed within vacuum housing 502. During operations, ion source 508 may transmit one or more ion beams 510 to a target assembly 512 disposed within vacuum housing 502. In examples, target rod 516 may act as an electrical connector to HV power supply 520, and a thermal conductor to transfer any excessive heat from target assembly 512 outside of neutron generating tube 500. In this way, D₂ and T₂ molecular ions, generated from ion source 508, may be accelerated to bombard target film 514 loaded with the same gas. During bombardment, the D-T, or T-D fusion reactions occur at a given high voltage to generate neutrons. The D-D fusion reaction may have a low cross-section in a typical HV region.

Suppressor 522, which is an added metal electrode, may be utilized to suppress secondary electron emission from target film 514. As illustrated, suppressor 522 may be connected via a corona shield 524 outside vacuum housing 502 to high voltage (HV) power supply 520. Additionally, suppressor 522 may operate and function to accelerate ion beam 510 for bombarding target assembly 512, which may create a D/T fusion reaction to generate neutrons. A corona shield 524 may operate and function to smoothen an electrical field that is generated outside target assembly 512 by neutron generating tube 500. Corona shield 524 may function as the electrical connector between HV power supply 520 and suppressor 522. During an example operation, a resistor 518 that may be 2 MΩ, and an ion beam 510 of 100 μA, may produce an automatic voltage difference of 200 V between suppressor 522 and target film 514, to send back the secondary low-energy electrons. For a given HV power supply 520 of 100 kV, an ion beam 510 of 100 μA current, and a saturated target film 514 (for this example made of Titanium) at a level of 1.8-2.0 D/T atoms per Titanium atom, a neutron yield typically of 3×10⁸ n/sec may be generated. The generated neutrons may then be transmitted from neutron generator 110 as described above.

FIG. 6 illustrates another example of neutron generating tube 500. In this example, neutron generating tube 500 may comprise a hot-cathode ion source 600 that may generate an ion beam 510 and transmit ion beam 510 to target assembly 512. As illustrated, hot-cathode ion source 600 may comprise a hot-cathode 601, a grid electrode 602, and an extractor electrode 604. During operations, hot-cathode ion source 600 does not need a magnetic field to trap ions and electrons to form plasma. Thus, one of the advantages of hot-cathode ion source 600 is that ion beam 510 may be quickly switched on/off by controlling the electron mission from hot-cathode 601 to stop ionization and at the same time by controlling ion beam 510 extraction inside hot-cathode ion source 600. This may allow for fast and sharp pulsing, as illustrated and described in FIG. 4, possible with the rise and fall times in a 200-500 nano second range. During operation, V_{R}, V_{HC}, V_{G}, and V_{E} may be applied as controlling voltages with electrical currents on gas reservoir 506, hot cathode 601, grid electrode 602, and extractor electrode 604. Grid electrode 602 may function as a control for electron emission from surface 606 of hot cathode 601, and a driver for electron beam 610 inside the ion source 600, whereas extractor electrode 604 may function together with grid electrode 602 for extraction of ion beam 510. As illustrated, r, d, and Lᵢ are radius of surface 606 of hot cathode 601, the distance between surface 606 of hot cathode 601 to the grid on the grid electrode 602, and the length of the ion source volume, respectively. In examples, Lᵢ may be about 1.0 cm. Iₑ and Iᵢₒₙ represent the electron beam 610 and extracted ion beam 510 currents. In examples, le may be about 30-50 mA. Since the hydrogen molecular ionization cross section peaks between 50-200 eV, relatively low control voltages (<250 v) for V_{G}, and V_{E} may be utilized to operate hot-cathode ion source 600. Lₐ is the distance from extractor electrode 604 to the target film 514 in the acceleration column, and V_{S}, V_{T} are ion acceleration voltages applied to suppressor 522 and target film 514. Given a gas pressure inside vacuum housing 502 of 1-5 mTorr and 50 mA electron current in a 1.0 cm ion source geometry, a 150 μA ion current may be extracted routinely assuming a 100% efficiency for ion extraction. Both transparencies of grid electrode 602 and extractor electrode 604 may reduce the final ion current. However, the gas pressure is a parameter which may be adjusted higher to compensate for any ion losses.

During operations, gas reservoir 506 may be heated to generate a few m Torr gas pressure. Hot cathode 601 (with a 4-5 mm diameter, and d in a range of 1-2 mm) may be heated so that plenty electron charges hover near its surface space 606. By applying a grid voltage V_{G} in a range of 200-250 V, an electron beam 610 with a current of 30-50 mA may transmit inside hot cathode ion source 600 with a pass length of 1.0 cm. Through ionization processes, ions with a beam current of more than 100 μA in ion beam 510 may be extracted with the extractor at V_{E} ranging from 0 to −50 V. Furthermore, a pulsed operation, with a typically 20% duty factor, may be achieved by turning on and off V_{G}, and V_{E} in sync, with a 200-500 ns rise and fall times.

Generally, V_{S} and V_{T} are ion acceleration voltages applied to suppressor 522 and target film 514 which may be typically around 100 kV. Lₐ the distance from extractor electrode 604 to target film 514 in the acceleration column, ranges from 2-4 cm, depending on ion beam optics. Target film 514, typically Titanium, may have a diameter of 6-10 mm, with a thickness of 3-5 μm, which may be saturated with D/T mixed gas. As stated, for a given HV power supply 520 of 100 kV, an ion beam 510 of 100 μA current, and a saturated target film 514 of Titanium at a level of 1.8-2.0 D/T atoms per Titanium atom, a neutron yield typically of 3×10⁸ n/sec may be generated with 1000 hours of neutron generating tube 500 lifetime expectancy.

Presently, many neutron generating tubes 500 comprise hot cathode ion source 600 which may emit electrons for a direct ionization of gas molecules to produce the D/T ions. However, there are multiple challenges in constructing a target system for a neutron generating tube 500 with a hot cathode ion source 600. For example, complex tube structure and compact geometry make construction of target assembly 512 difficult. Another challenge, due to sputtering of material for target film 514 coming from the ion beam bombardment, target assembly 512 should include a system to protect the inner surface of insulating tube 504 from deposition of sputtered metal particles to extend the lifetime of neutron generating tubes 500. Additionally, due to development of avalanche from charged particles inside the tube acceleration column created by HV power supply 520, target assembly 512 may comprise an arcing damping mechanism, such as conductive ring 900 described below, to maintain operational stability. Further challenges may be seen in thermal heating of target assembly 512, which should be controlled during operation (especially at elevated temperatures) to avoid target degassing (of D/T molecules) and maintain performance of neutron generating tube 500 in neutron yield.

Methods and systems are discussed below address the construction challenges discussed above. Illustrated figures are given to present construction of at least a part of neutron generating tube 500 with a focus on target assembly 512 while leaving hot-cathode ion source 600 aside. As discussed below, methods and systems may be utilized to form a shielding structure 804 as an extended structure on extractor electrode 604 in combination with a suppressor 522 to protect an inner surface of ceramic insulating tube 504 from deposition of sputtered metal particles from target film 514 or other places. The extended structures may intercept the sputtered metal particles and shadow ceramic insulating tube 504 from deposition of sputtered metal particles. During construction, a conductive coating ring may be disposed on the inner surface of ceramic insulating tube 504 for damping arcing during operation. Additionally, the use of a HV connection 521, such as a copper substrate, copper wire, and/or other copper medium, is attached to target rod 516 for thermal dissipation to prevent over-heating of target rod 516 and target film 514, especially for operation at elevated temperatures.

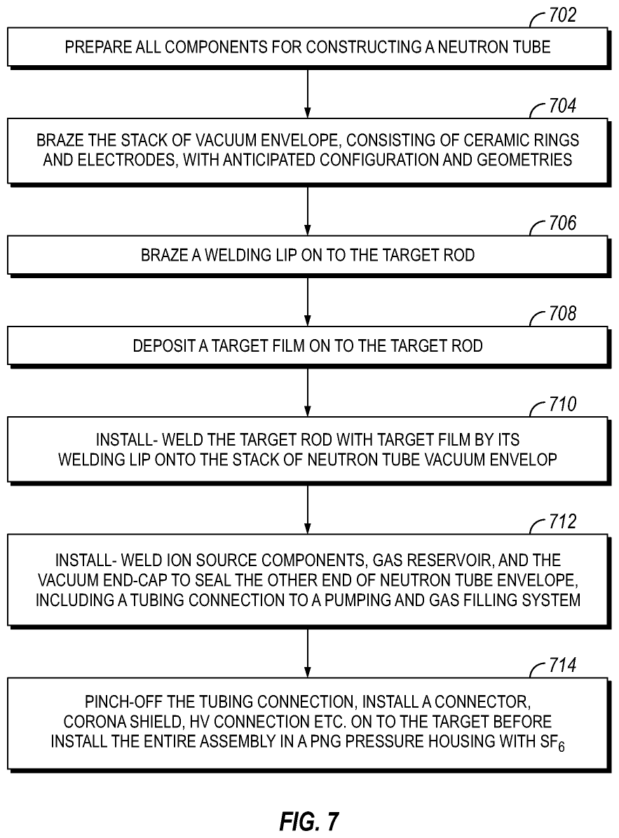

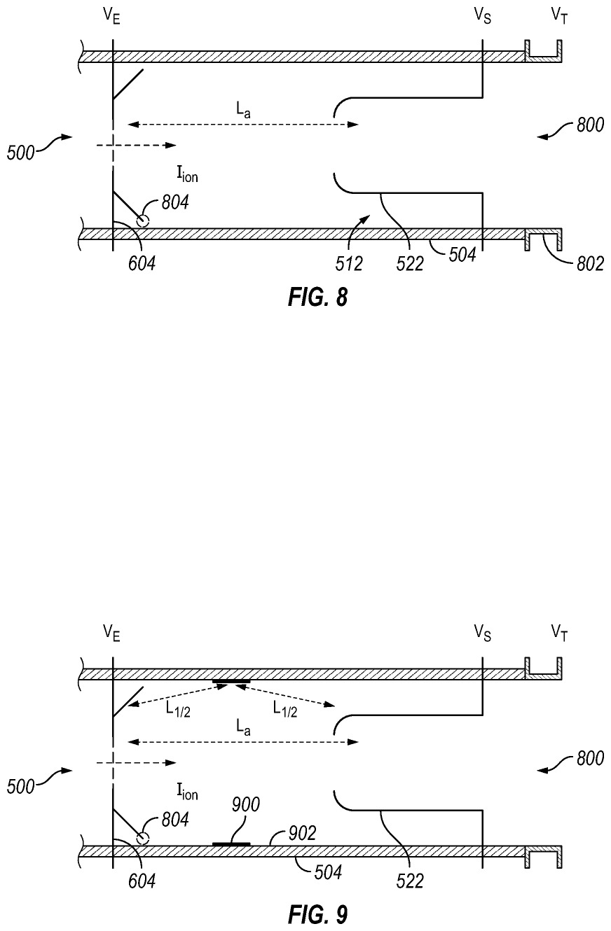

FIG. 7 illustrates workflow 700 for constructing neutron generating tube 500. Workflow 700 may begin with block 702 in which components for constructing neutron generating tube 500 may be prepared. FIG. 8 illustrates preparing target assembly 512, in block 702, for construction based at least in part on a tube architecture with an open structure. As illustrated, neutron generating tube 500 may open at a first end 800, which may allow for the insertion of target rod 516. First end 800 may comprise a welding ring 802 attached to ceramic insulating tube 504, which may be attached through a step of brazing the welding ring 802 to ceramic insulating tube 504. Welding ring 802 may provide a joining point for welding the target rod 516 in place. Additionally, FIG. 8 illustrates suppressor 522 disposed within target assembly 512 opposite extractor electrode 604 and shielding structure 804. Shielding structure 804 may be attached to extractor electrode 604 before brazing. Shielding structure 804, together with suppressor 522, may shield ceramic insulating tube 504 from deposition of sputtered metal particles during operation.

Referring back to FIG. 7, after all components have been prepared for construction in block 7002, in block 704, neutron generating tube 500 with one or more nickel-cobalt ferrous alloy washers used as electrodes and one or more ceramic housing rings as insulating spacers in a designed configuration with chosen geometry is brazed together, as a sealed vacuum enclosure. Nickel-cobalt ferrous alloy is chosen for material of washers due to its thermal expansion coefficient matching that of ceramic. The structure of neutron generating tube 500 should be vacuum tight, and mechanically robust (for shocks and vibrations in the LWD applications) after brazing. FIG. 9 illustrates the placement of conductive coating ring 900 during construction in block 704. Conductive coating ring 900 may be disposed along inner surface 902 of insulating tube 504, between extractor electrode 604 and suppressor 522. Conductive coating ring 900 may have a width in a range of 5-10 mm and may be disposed about equidistance from extractor electrode 604 and suppressor 522. In examples, conductive coating ring 900 may be coated with Titanium Diboride, or any other suitable material. During placement, conductive coating ring 900 may be coated on inner surface 902 of insulating tube 504 at the given position after the vacuum envelope of neutron generating tube 500 is brazed together. Alternatively, conductive coating ring 900 may be metalized by the ceramic vendor with, for example, a Silver and Copper alloy on inner surface 902 of insulating tube 504 at the given position before brazing of the vacuum envelope of neutron generating tube 500.

Conductive coating ring 900 may be utilized to prevent and/or reduce arcing. During operation, neutron generating tube 500 may produce arcing, due to high voltage stress, which may range from 70-150 kV, in a very compact geometry with a gaseous environment. As illustrated in FIG. 9, suppressor 522 at a 100 kV may be about 2-4 cm away from extractor 604, which is roughly at the ground potential, while the acceleration column is filled with a few mTorr D/T gas and running with a 100 μA ion current. Arcing may often last for a few seconds or even a couple of minutes, before damping down naturally due to reduced or reset of high voltage.

Conductive coating ring 900 may function and operate as an electric island, floating in between suppressor 522 and extractor 604, nominally in the middle position, with an effective potential of 30-70 kV. When arcing or a gas avalanche develops between conductive coating ring 900 and suppressor 522, conductive coating ring 900 may collect charges, i.e., electrons from the gas avalanche. Thus, conductive coating ring 900 effective voltage potential may tilt toward suppressor 522, shortening the voltage potential difference between conductive coating ring 900 and suppressor 522. This may automatically stop the arcing or stop the gas avalanche. As neutron generating tube 500 dampens down naturally, the charges collected on conductive coating ring 900 may dissipate due to collisions of gas molecular ions, and its effective voltage potential may gradually re-set back to its nominal position of 50 kV. Thus, conductive coating ring 900 behaves like a voltage potential pendulum. It forms an auto damping mechanism for arcing.

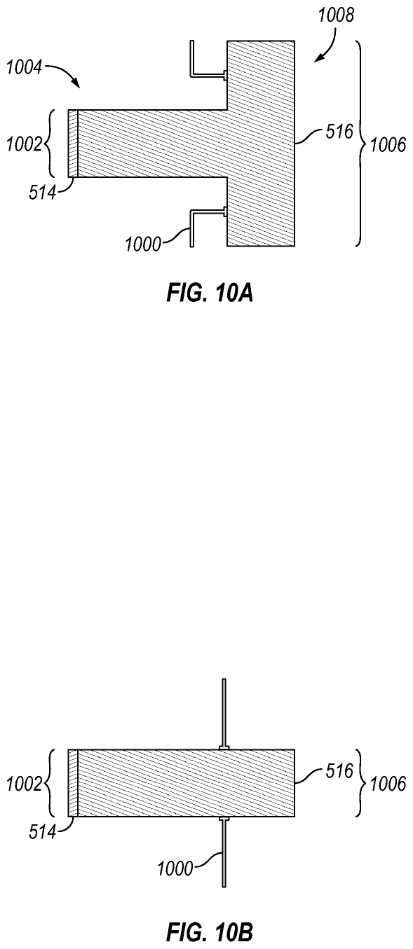

Referring back to FIG. 7, after brazing has been completed in block 704, a welding lip may be brazed to target rod 516 of target assembly 512 (e.g., referring to FIG. 6). FIGS. 10A and 10B illustrate brazing a welding lip 1000 to target rod 516, referring to block 706 of FIG. 7. In examples, target rod 516 may be manufactured and prepared, per choices of geometry. Next, target rod 516 may be brazed with a welding lip 1000 to match welding ring 802 disposed at first end 800 of neutron generating tube 500 (e.g., referring to FIG. 8). Referring back to FIG. 7, in block 708, subsequently after block 706, target rod 516 may be deposited with target film 514 in a thickness of 3-5 μm and with a diameter in a range of 6-10 mm. In examples, referring to FIG. 10 A, target rod 516 may have a first diameter 1002 at one end 1004 of target rod 516 and a second diameter 1006 at a second end 1008. Second diameter 1006 may be larger than first diameter 1002 for heat dissipation. In other examples, referring to FIG. 10 B, both first diameter 1002 and second diameter 1006 may have a uniform diameter for easy machining.

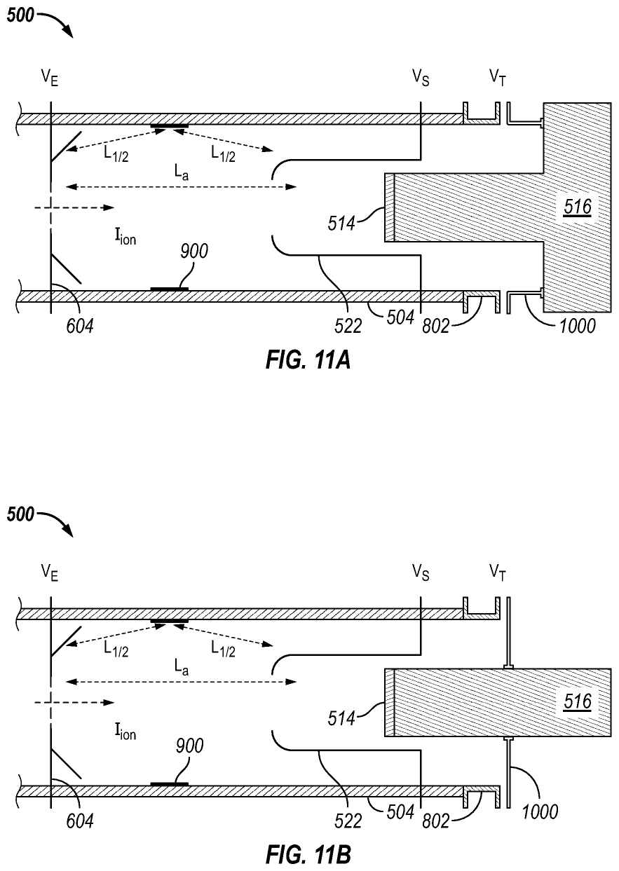

Referring back to FIG. 7, after target rod 516 has been prepared in blocks 706 and 708, in block 710 target rod 516 may be installed into neutron generating tube 500. FIGS. 11A and 11B illustrate placement and securement of target rod 516 to neutron generating tube 500. Target rod 516, by welding together welding lips 1000 to matching welding ring 802 at open end 800 (e.g., referring to FIG. 8) seals the vacuum tube together with vacuum housing 502 and insulating tube 504. As illustrated target film 514 may be disposed in the anticipated position inside suppressor 522. In examples, target film 514 may be about 3-4 cm away from extractor electrode 604. After installation of target rod 516 in block 710, in block 712, referring back to FIG. 7, all components such as hot cathode 601, gas reservoir 506, and an end part of vacuum housing 502 at an end opposite target assembly 512 may be installed. Sealed neutron generating tube 500 may be equipped with a copper tubing 503 at the end part of vacuum housing 502 (i.e., referring to FIG. 5), which may be connected to a vacuum pumping station and gas handling system for vacuum and D/T gas filling processing.

In block 714, after selected components have been installed and neutron tube processing is completed, copper tubing 503 of vacuum housing 502 of neutron generating tube 500 (e.g., referring to FIG. 5) may be pinched off after D/T gas is loaded. Then neutron generating tube 500 is sealed and ready to be deployed as a part of neutron generator 110 in a pulsed-neutron logging tool 102. Benefits of an open tube structure and sequential mounting of individual components utilizing workflow 700 may lead to a manufacturing process that may be simpler and easier, with precision, repeatability, and reliability. The added features for protecting the ceramic insulating walls, and for damping arcing, as well as the added target interface for thermal management further ensures a stable operation for the neutron generating tube in a downhole application at elevated temperatures with a longer lifetime.

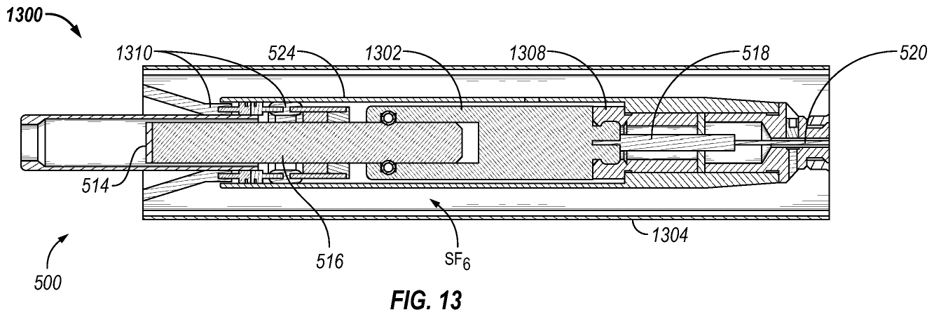

FIG. 13 illustrates a mechanical assembly 1300 of neutron generating tube 500 (e.g., referring to FIG. 5) in which a high-voltage (HV) connection to neutron generating tube 500 is shown. Further illustrated within neutron generation tube 500 is a target rod 516 and target film 514 disposed with suppressor 522. A HV connection 521, inside a pulsed neutron generator (PNG) housing 1304 filled with SF₆ gas. In examples, glass tubes 1310 instead of ceramic tubes are utilized as insulation to perform the same functionalities. As illustrated, a target connector 1302 may be slid on target rod 516 for HV electrical connection. Target connector 1302 may be the same metal as the metal that forms target rod 516 to extend the geometry of target rod 516, which may increase thermal dissipation. Target connector 1302 is followed by an insulator 1308 for mechanical mounting and electrical insulation, a resistor 518, and a corona shield 524 before connected to a HV power supply 520. The surrounding SF₆ gas, which is utilized for both HV insulation and thermal dissipation to the PNG housing 1304 due to gas molecular collisions, may have a pressure of 100-200 psi which further increases thermal dissipation. Based on thermal physics modeling, and a bench heating test experiment, the same target body temperature above ambient, with a ten watts operation, may be reduced to a ΔT=50-70° C. range. That is, for operation in a downhole environment with an ambient of 175° C., target rod 516 (as well as target film 514) may be maintained around 240° C. or below, to keep the target degassing as minimum as possible, in target assembly 512.

Improvements in methods and systems over current technology is found in that the neutron generating tube discussed above allow for easier installation of a target assembly with mechanical robustness, deposition prevention of sputtered metal particles, arcing damping mechanism, and target thermal management. This provides for stable operation, increased performance, and a longer lifetime, especially at elevated temperature for downhole applications. The improved target assembly, combined with the thermal management interface, as described in this disclosure in the previous sections, brings not only benefits for tube construction, but also benefits for tube operation. These methods and systems for easier construction of neutron generating tubes would save manufacturing time and resources, i.e., save costs. It would minimize the tube-to-tube variations, and it would cut down tube failures in manufacturing. It will make the tube structure more robust for LWD applications. The manufacturing process is simpler and easier, with precision, repeatability, and reliability. The added features for protecting the ceramic insulating walls, and for damping arcing, as well as the added target interface for thermal management further ensures a stable operation for the neutron generating tube in a down hole application at elevated temperatures with a longer lifetime.

For example, assuming a nominal operation with a 100 μA ion current to bombard the target at 100 kV in a downhole application at elevated temperatures, improvements may be seen in the use of the shield on the extractor, combined with the suppressor, that will shield the sputtered metal particles from depositing on to the surfaces of ceramic insulating walls. The ceramic insulating walls will last long for the target HV stand-off, to ensure a long tube lifetime. The conductive coating strip, positioned between the extractor and suppressor, will help damp any potential arcing during tube operation. This will ensure a stable operation with a constant neutron yield. The thermal management interface, for the connection of the target Copper rod to the HV power supply, will help to reduce the ΔT above ambient. This will reduce the target degassing when operated at elevated temperatures, maintaining the high neutron yield.

The preceding description provides various examples of the systems and methods of use disclosed herein which may contain different method steps and alternative combinations of components.
Statement 1: A method may comprise brazing a welding ring to a neutron generating tube at a first open end, brazing a welding lip to a target rod, and/or disposing the target rod into the neutron generating tube, wherein the welding lip is at least in part in contact with the welding ring. The method may further comprise welding the welding lip to the welding ring to form a vacuum envelope, disposing a copper tubing at a second open end of the neutron generating tube opposite the first open end, and pinching off the copper tubing to form a sealed vacuum in the neutron generating tube.
Statement 2: The method of statement 1, wherein the target rod is copper.
Statement 3: The method of any previous statements, further comprising disposing a target film on the target rod.
Statement 4: The method of statement 3, wherein the target film is Scandium, Titanium, or Zirconium, or any combination of these materials in a multi-layered form.
Statement 5: The method of any previous statements 1-3, further comprising disposing an ion source into the neutron generating tube.
Statement 6: The method of statement 5, wherein the ion source further comprises a hot cathode.
Statement 7: The method of statement 5, further comprising disposing a grid between the ion source and the target rod.
Statement 8: The method of statement 7, further comprising disposing an extractor electrode between the grid and the target rod, wherein the grid and the extractor electrode direct an ion beam transmitted from the ion source.
Statement 9: The method of any previous statements 1-3 or 5, further comprising disposing a gas reservoir into the neutron generating tube.
Statement 10: The method of statement 9, wherein the gas reservoir is Titanium or Zirconium.
Statement 11: The method of statement 10, wherein the gas reservoir stores deuterium and tritium.
Statement 12: The method of any previous statements 1-3, 5, or 9, further comprising installing a high voltage connection to the target rod of the neutron generating tube.
Statement 13: The method of any previous statements 1-3, 5, 9, or 12, further comprising installing a corona shield to the neutron generating tube.
Statement 14: The method of statement 13, further comprising attaching a high voltage to the target rod.
Statement 15: The method of statement 14, further comprising a resistor that connects the high voltage to the target rod and is disposed within the corona shield.
Statement 16: The method of any previous statements 1-3, 5, 9, 12, or 13, further comprising disposing the neutron generating tube into a pulsed neutron generator housing.
Statement 17: The method of statement 16, wherein the pulsed neutron generator housing is filled with a SF₆ gas.
Statement 18: The method of any previous statements 1-3, 5, 9, 12, 13, or 16, wherein the target rod is disposed into a suppressor.
Statement 19: The method of statement 18, further comprising disposing a conductive coating ring on an inner surface of the neutron generating tube between the suppressor and an extractor electrode.
Statement 20: The method of statement 19, wherein the conductive coating ring is Titanium Diboride.

It should be understood that, although individual examples may be discussed herein, the present disclosure covers all combinations of the disclosed examples, including, without limitation, the different component combinations, method step combinations, and properties of the system. It should be understood that the compositions and methods are described in terms of “comprising,” “containing,” or “including” various components or steps, the compositions and methods can also “consist essentially of” or “consist of” the various components and steps. Moreover, the indefinite articles “a” or “an,” as used in the claims, are defined herein to mean one or more than one of the elements that it introduces.

For the sake of brevity, only certain ranges are explicitly disclosed herein. However, ranges from any lower limit may be combined with any upper limit to recite a range not explicitly recited, as well as ranges from any lower limit may be combined with any other lower limit to recite a range not explicitly recited, in the same way, ranges from any upper limit may be combined with any other upper limit to recite a range not explicitly recited. Additionally, whenever a numerical range with a lower limit and an upper limit is disclosed, any number and any included range falling within the range are specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values even if not explicitly recited. Thus, every point or individual value may serve as its own lower or upper limit combined with any other point or individual value or any other lower or upper limit, to recite a range not explicitly recited.

Therefore, the present examples are well adapted to attain the ends and advantages mentioned as well as those that are inherent therein. The particular examples disclosed above are illustrative only and may be modified and practiced in different but equivalent manners apparent to those skilled in the art having the benefit of the teachings herein. Although individual examples are discussed, the disclosure covers all combinations of all of the examples. Furthermore, no limitations are intended to the details of construction or design herein shown, other than as described in the claims below. Also, the terms in the claims have their plain, ordinary meaning unless otherwise explicitly and clearly defined by the patentee. It is therefore evident that the particular illustrative examples disclosed above may be altered or modified and all such variations are considered within the scope and spirit of those examples. If there is any conflict in the usages of a word or term in this specification and one or more patent(s) or other documents that may be incorporated herein by reference, the definitions that are consistent with this specification should be adopted.

What is claimed is:

1. A method comprising:
brazing a welding ring to a neutron generating tube at a first open end;
brazing a welding lip to a target rod;
disposing the target rod into the neutron generating tube, wherein the welding lip is at least in part in contact with the welding ring;
welding the welding lip to the welding ring to form a vacuum envelope;
disposing a copper tubing at a second open end of the neutron generating tube opposite the first open end; and
pinching off the copper tubing to form a sealed vacuum in the neutron generating tube.

2. The method of claim 1, wherein the target rod is copper.

3. The method of claim 1, further comprising disposing a target film on the target rod.

4. The method of claim 3, wherein the target film is Scandium, Titanium, or Zirconium, or any combination of these materials in a multi-layered form.

5. The method of claim 1, further comprising disposing an ion source into the neutron generating tube.

6. The method of claim 5, wherein the ion source further comprises a hot cathode.

7. The method of claim 5, further comprising disposing a grid between the ion source and the target rod.

8. The method of claim 7, further comprising disposing an extractor electrode between the grid and the target rod, wherein the grid and the extractor electrode direct an ion beam transmitted from the ion source.

9. The method of claim 1, further comprising disposing a gas reservoir into the neutron generating tube.

10. The method of claim 9, wherein the gas reservoir is Titanium or Zirconium.

11. The method of claim 10, wherein the gas reservoir stores deuterium and tritium.

12. The method of claim 1, further comprising installing a high voltage connection to the target rod of the neutron generating tube.

13. The method of claim 1, further comprising installing a corona shield to the neutron generating tube.

14. The method of claim 13, further comprising attaching a high voltage to the target rod.

15. The method of claim 14, further comprising a resistor that connects the high voltage to the target rod and is disposed within the corona shield.

16. The method of claim 1, further comprising disposing the neutron generating tube into a pulsed neutron generator housing.

17. The method of claim 16, wherein the pulsed neutron generator housing is filled with a SF₆ gas.

18. The method of claim 1, wherein the target rod is disposed into a suppressor.

19. The method of claim 18, further comprising disposing a conductive coating ring on an inner surface of the neutron generating tube between the suppressor and an extractor electrode.

20. The method of claim 19, wherein the conductive coating ring is Titanium Diboride.
